(19) United States
(12) Patent Application Publication
(10) Pub. No.: US 2013/0271914 A1
(43) Pub. Date: Oct. 17, 2013

(54) ELECTRONIC DEVICE WITH AIR DUCT

(71) Applicants: HONG FU JIN PRECISION INDUSTRY (SHENZHEN) CO., LTD., Shenzhen (CN); HON HAI PRECISION INDUSTRY CO., LTD., New Taipei (TW)

(72) Inventor: Shuang FU, Shenzhen (CN)

(73) Assignees: HON HAI PRECISION INDUSTRY CO., LTD., New Taipei (TW); HONG FU JIN PRECISION INDUSTRY (ShenZhen) CO., LTD., Shenzhen (CN)

(21) Appl. No.: 13/718,507

(22) Filed: Dec. 18, 2012

(30) Foreign Application Priority Data
Apr. 13, 2012 (CN) 201210107521.8

(51) Int. Cl. H05K 7/20

(52) U.S. Cl. CPC H05K 7/20127
USPC 361/692

(57) ABSTRACT

An electronic device includes an enclosure, a circuit board, and an air duct. The enclosure includes a bottom plate, the bottom plate defining a vent opening. The circuit board is attached to the bottom plate. A first heat generating part and a second generating part are located on the circuit board. The air duct is secured to the circuit board. The air duct defines a first air flows guiding passage and a second airflow guiding passage. When air flows through the vent opening, the first air flows guiding passage is configured to guide air flows to dissipate heat generated by the first heat generating part, and the second air flows guiding passage is configured to guide air flows to dissipate heat generated by the second heat generating part.

### BACKGROUND

1. Technical Field

The present disclosure relates to electronic devices, and particularly to an electronic device with an air duct.

2. Description of Related Art

Air duct is widely used for facilitating heat dissipation of electronic components of a computer system. The air duct covers on the electronic components of the computer system to guide airflow from fans to the electronic components. For a large sized computer system, such as a server system, which has a great number of electronic components, a large sized air duct is needed to carry out a massive amount of heat dissipation of electronic components. When some of the electronic components in the computer system need to be replaced or repaired, the whole air duct must be removed. Such process is inconvenient and time consuming

Therefore, there is room for improvement within the art.

### BRIEF DESCRIPTION OF THE DRAWINGS

Many aspects of the embodiments can be better understood with references to the following drawings. The components in the drawings are not necessarily drawn to scale, the emphasis instead being placed upon clearly illustrating the principles of the embodiments. Moreover, in the drawings, like reference numerals designate corresponding parts throughout the several views.

FIG. 1 is an exploded, isometric view of an embodiment of an electronic device.

FIG. 2 is an isometric view of the air duct of FIG. 1.

FIG. 3 is a partial, assembled view of the electronic device of FIG. 1.

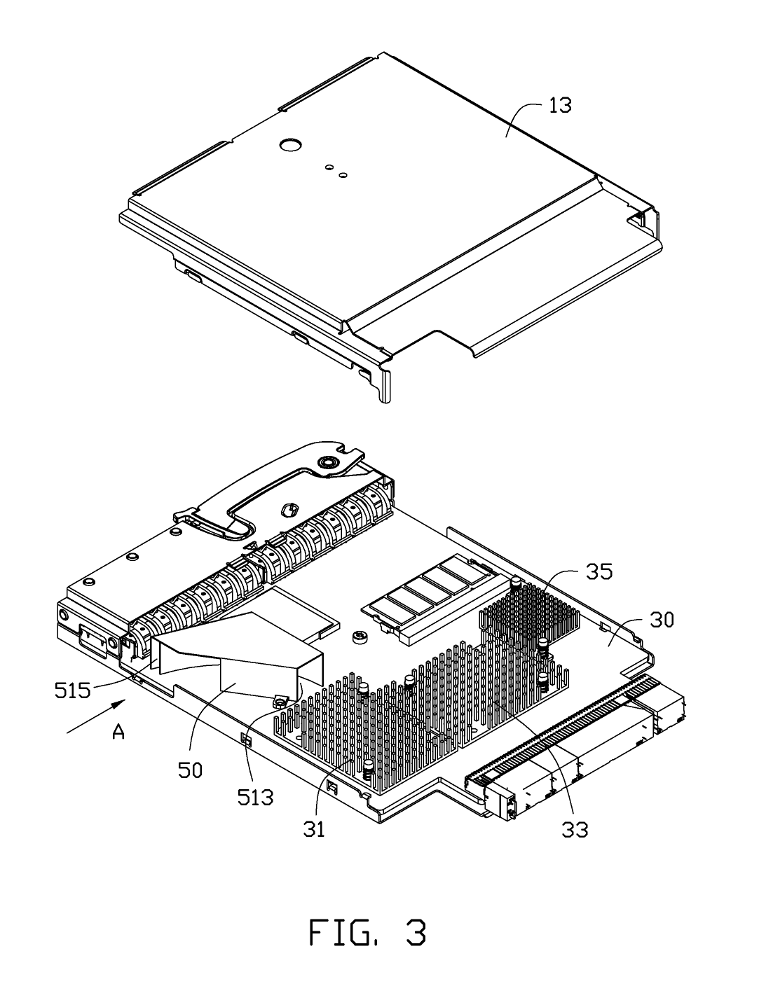

FIG. 4 is an assembled view of the electronic device of FIG. 1.

### DETAILED DESCRIPTION

The disclosure is illustrated by way of example and not by way of limitation in the figures of the accompanying drawings in which like references indicate similar elements. It should be noted that references to “an” or “one” embodiment in this disclosure are not necessarily to the same embodiment, and such references mean at least one.

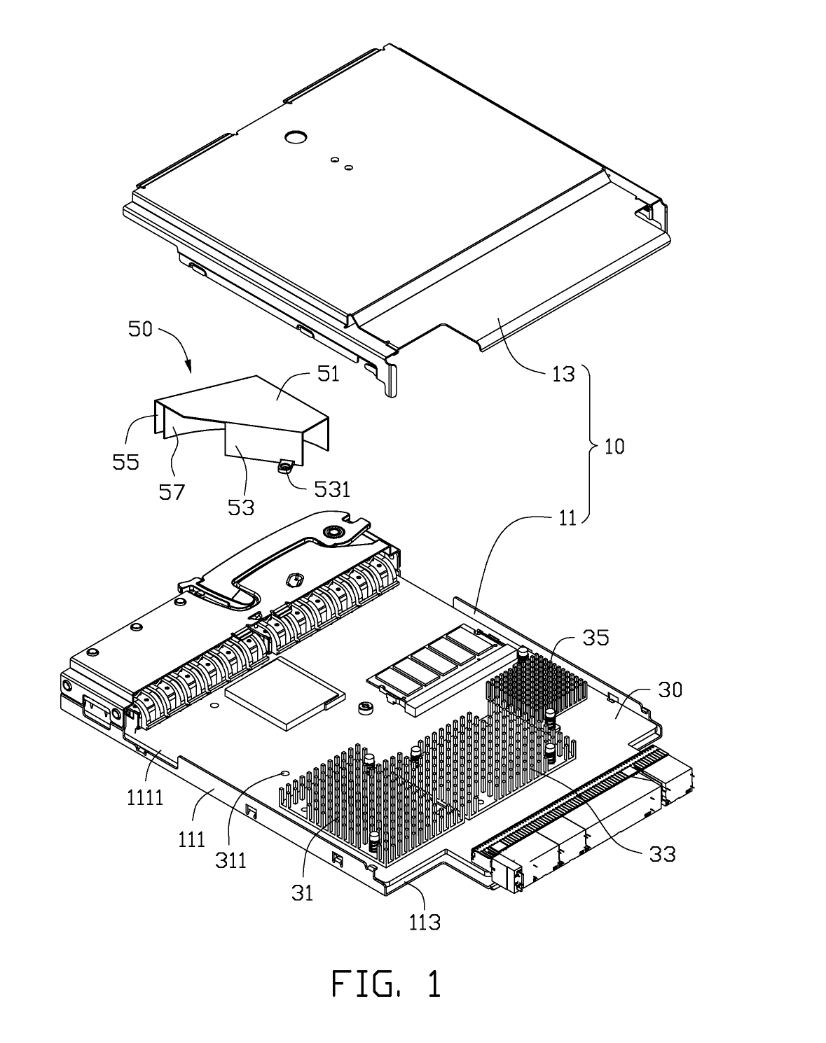

FIG. 1 illustrates an electronic device in one embodiment. The electronic device includes an enclosure 10, a circuit board 30, and an air duct 50 attached to the circuit board 30.

The enclosure 10 includes a base 11 and a cover 13 configured to cover the base 11. The base 11 includes a bottom plate 113 and a flange 111, extending from an edge of the bottom plate 113. The flange 111 defines a vent opening 1111 for guiding airflow into the enclosure 10.

The circuit board 30 is secured to the bottom plate 113 and defines two installation holes 311 corresponding to the air duct 50. A first heat generating part 31, a second heat generating part 33, and a third heat generating part 35 are located on the circuit board 30. The first heat generating part 31, the second heat generating part 33, and the third heat generating part 35 are substantially in a line.

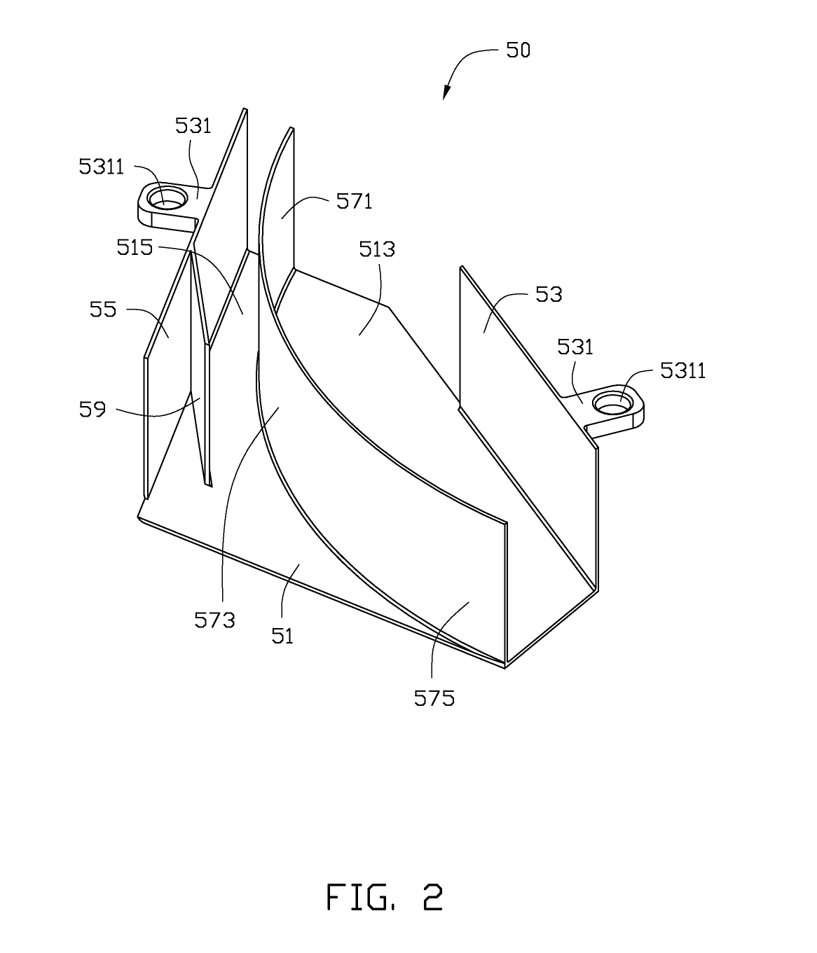

Referring to FIG. 2, the air duct 50 includes a top wall 51, a first sidewall 53, a second sidewall 55, and a dividing plate 57. The top wall 51 is substantially parallel to the circuit board 30. The first sidewall 53 and the second sidewall 55 extend from two edges of the top wall 51. A first plane contains a first sidewall 53, and a second plane contains a second sidewall 55. An obtuse angle is defined between the first plane and the second plane. The dividing plate 57 is located on the top wall 51 and positioned between the first sidewall 53 and the second sidewall 55. In one embodiment, the dividing plate 57 is arcuate, but not limited to arc-shapes. The first sidewall 53, the top wall 51 and the dividing plate 57 cooperatively define a first airflow guiding passage 513. The second sidewall 55, the top wall and the dividing plate 57 cooperatively define a second airflow guiding passage 515. The dividing plate 57 includes a front portion 571, a middle portion 573, and an end portion 575. In one embodiment, the front portion 571 is substantially parallel to the second sidewall 55, and the end portion 575 is substantially parallel to the first sidewall 53. The air duct 50 further includes a blocking plate 59. The blocking plate 59 is located on an inner side of the second sidewall 55, connected with the second sidewall 55. The blocking plate 59 can control airflow speed of the second airflow guiding passage 515 and is substantially parallel to the middle portion 573 of the dividing plate 57. An obtuse angle is defined between the second sidewall 55 and the blocking plate 59. Two securing tabs 531 extend from the first sidewall 53 and the second sidewall 55, respectively. A securing hole 5531 is defined in each of the two securing tabs 531, corresponding to each of the two installation holes 311.

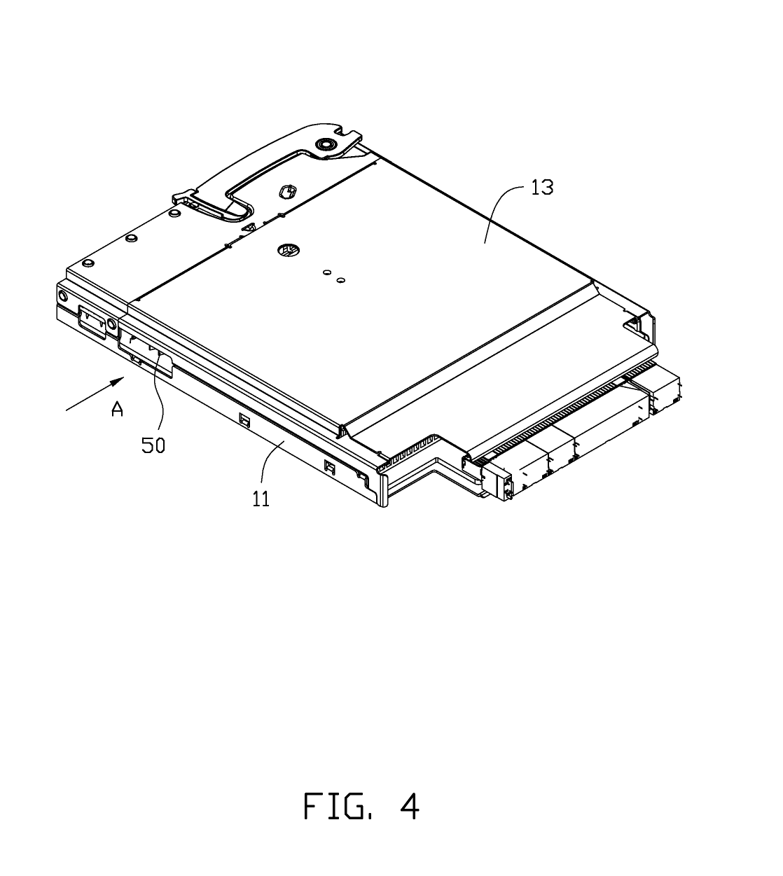

Referring to FIGS. 4 and 5, to install the air duct 50, the air duct 50 is attached to the circuit board 30, and the first sidewall 53 is adjacent to the first heat generating part 31. Each securing hole 5531 is aligned with each installation hole 311. Two locking members (not shown) are screwed into the securing hole 5311 and the installation hole 311, to secure the air duct 50 to the circuit board 30. In this position, an obtuse angle is defined between the flange 111 and the first sidewall 53, and the second sidewall 55 is substantially perpendicular to the flange 111.

In use, airflow is guided into the enclosure 10 through the vent opening 1111. The first airflow guiding passage 513 guides the airflow to dissipate the first heat generating part 31, and the second airflow guiding passage 515 guides the airflow to dissipate the second heat generating part 33 and the third heat generating part 35. Thus, the air duct 50 can dissipate heat generated by a plurality of heat generating parts.

When some of the heat generating parts need to be replaced or repaired, the air duct does not need to be removed accordingly.

It is to be understood, however, that even though numerous characteristics and advantages have been set forth in the foregoing description of embodiments, together with details of the structures and functions of the embodiments, the disclosure is illustrative only and changes may be made in detail, especially in matters of shape, size, and arrangement of parts within the principles of the disclosure to the full extent indicated by the broad general meaning of the terms in which the appended claims are expressed.

What is claimed is:

1. An electronic device comprising:
an enclosure, the enclosure comprising a bottom plate, and the bottom plate defines a vent opening;
a circuit board attached to the bottom plate, a first heat generating part and a second heat generating part are located on the circuit board; and
an air duct secured to the circuit board, and the air duct defines a first airflow guiding passage and a second airflow guiding passage;
wherein when air flows through the vent opening, the first airflow guiding passage is configured to guide air flows to dissipate heat generated by the first heat generating part; and the second air flows guiding passage is configured to guide air flows to dissipate heat generated by the second heat generating part.

2. The electronic device of claim 1, wherein the air duct comprises a top wall, a first sidewall, a second sidewall, and a dividing plate; the top wall and the second sidewall are located on two edges of the top wall, and the dividing plate is located on the top wall and between the first sidewall and the second sidewall.

3. The electronic device of claim 2, wherein the first sidewall and the dividing plate cooperatively define the first airflow guiding passage, and the second sidewall and the dividing plate cooperatively define the second airflow guiding passage.

4. The electronic device of claim 2, wherein the dividing plate comprises a front portion and an end portion, the front portion is substantially parallel to the second sidewall, and the end portion is substantially parallel to the first sidewall.

5. The electronic device of claim 2, wherein the air duct further comprises a blocking board, and the blocking board is connected to the second sidewall and configured to control airflow speed through the second airflow guiding passage.

6. The electronic device of claim 5, wherein the dividing plate comprises a middle portion, and the middle portion is substantially parallel to the blocking board.

7. The electronic device of claim 6, wherein an obtuse angle is defined between the middle portion and the second sidewall.

8. The electronic device of claim 2, wherein the enclosure further comprises a flange, the flange is located on the bottom plate, an obtuse angle is defined between the flange and the first sidewall, and the second sidewall is substantially perpendicular to the flange.

9. An electronic device comprising:
an enclosure, the enclosure comprising a bottom plate, the bottom plate defining a vent opening;
a circuit board attached to the bottom plate, a first heat generating part and a second heat generating part being located on the circuit board; and
an air duct secured to the circuit board, the air duct comprising a top wall, a first sidewall, a second sidewall, and a dividing plate; the first sidewall, the dividing plate, and the top wall cooperatively defining a first airflow guiding passage; the second sidewall, the dividing plate, and the dividing plate cooperatively defining a second airflow guiding passage;
wherein when air flows through the vent opening, the first airflow guiding passage is configured to guide air flows to dissipate heat generated by the first heat generating part; and the second air flows guiding passage is configured to guide air flows to dissipate heat generated by the second heat generating part.

10. The electronic device of claim 9, wherein the dividing plate is located on the top wall and between the first sidewall and the second sidewall.

11. The electronic device of claim 9, wherein a first plane with the first sidewall, and a second plane with the second sidewall, and an obtuse angle is defined between the first plane and the second plane.

12. The electronic device of claim 9, wherein the dividing plate comprises a front portion and an end portion, the front portion is substantially parallel to the second sidewall, and the end portion is substantially parallel to the first sidewall.

13. The electronic device of claim 9, wherein the air duct further comprises a blocking board, and the blocking board is connected to the second sidewall and configured to control airflow speed of the second airflow guiding passage.

14. The electronic device of claim 13, wherein the dividing plate comprises a middle portion, and the middle portion is substantially parallel to the blocking board.

15. The electronic device of claim 14, wherein an obtuse angle is defined between the middle portion and the second sidewall.

16. The electronic device of claim 9, wherein the enclosure further comprises a flange, the flange is located on the bottom plate, an obtuse angle is defined between the flange and the first sidewall, and the second sidewall is substantially perpendicular to the flange.
